(19) United States
(12) Patent Application Publication
(10) Pub. No.: US 2016/0205764 A1
(43) Pub. Date: Jul. 14, 2016

(54) FLEXIBLE DISPLAY DEVICE

(71) Applicant: Samsung Display Co., Ltd., Yongin-City (KR)

(72) Inventor: Jun NAMKUNG, Asan-si (KR)

(21) Appl. No.: 14/788,344

(22) Filed: Jun. 30, 2015

(30) Foreign Application Priority Data
Jan. 14, 2015 (KR) 10-2015-0006783

(51) Int. Cl. H05K 1/02; H05K 1/11; H05K 1/18

(52) U.S. Cl. CPC H05K 1/028; H05K 1/181; H05K 1/111; H05K 2201/10128

(57) ABSTRACT

A flexible display device includes a flexible substrate including a display area and a non-display area, an anti-reflective layer positioned in the display area, and a pad portion positioned in the non-display area. The pad portion includes a pad complementary film having an inclined surface.

### CROSS-REFERENCE TO RELATED APPLICATION

This application claims priority to and the benefit of Korean Patent Application No. 10-2015-0006783 filed in the Korean Intellectual Property Office on Jan. 14, 2015, the entire contents of which are incorporated herein by reference.

### BACKGROUND

(a) Technical Field

The present disclosure generally relates to a flexible display device.

(b) Description of the Related Art

A display device, such as a liquid crystal display (LCD), an organic light emitting diode display (OLED display), or an electrophoretic display, typically includes a field generating electrode and an electro-optical active layer. For example, the organic light emitting diode display includes an organic emission layer as the electro-optical active layer. The electric field generating electrode may be connected to a switching device such as a thin film transistor or the like to receive a data signal, and the electro-optical active layer converts the data signal into an optical signal to display an image.

Among the different types of display devices, the organic light emitting diode display has self-emitting characteristics. Unlike a liquid crystal display, the organic light emitting diode display does not require a separate light source, and therefore a thickness and weight of the organic light emitting diode display may be reduced. In addition, the organic light emitting diode display has desirable characteristics such as low power consumption, high luminance, fast response time, etc. Generally, the organic light emitting diode display includes a substrate, an organic light emitting diode positioned on the substrate, and an encapsulation encapsulating the organic light emitting diode together with the substrate.

Recently, a flexible display device including a flexible substrate made of an organic material such as polyimide has been developed. The flexible display device may be manufactured by forming the flexible substrate on a support substrate such as glass, forming the organic light emitting diode and the encapsulation on the flexible substrate, and then peeling the flexible substrate from the support substrate.

To maximize flexible characteristics, the flexible display device does not incorporate the glass substrate. Instead, the flexible display device uses a lower protective film including an adhesive layer to protect a surface of the flexible substrate.

When the flexible display device undergoes bending or folding, a stress is induced which causes a neutral plane in the flexible display device to suddenly change. As a result, cracks may occur in the pads of the flexible display device.

The above information disclosed in the Background section is to enhance understanding of the background of the inventive concept and therefore it may contain information that does not form the prior art that is already known in this country to a person of ordinary skill in the art.

### SUMMARY

The present disclosure addresses at least the above issues relating to the change in neutral plane when a flexible display device undergoes bending or folding.

According to an exemplary embodiment of the inventive concept, a flexible display device is provided. The flexible substrate includes a display area and a non-display area, an anti-reflective layer positioned in the display area, and a pad portion positioned in the non-display area. The pad portion includes a pad complementary film having an inclined surface.

In some embodiments, the pad complementary film may be connected to the anti-reflective layer, and the inclined surface of the pad complementary film may be connected to an inclined surface of the anti-reflective layer.

In some embodiments, the pad complementary film may include at least one surface formed with the inclined surface.

In some embodiments, the anti-reflective layer may be positioned in a portion of the non-display area, and connected to the pad complementary film through the at least one surface formed with the inclined surface.

In some embodiments, the pad complementary film may include three surfaces formed with inclined surfaces, and the inclined surfaces of the three surfaces of the pad complementary film may be connected to the anti-reflective layer.

In some embodiments, the pad complementary film may be connected to the anti-reflective layer in a first section of the flexible display device, and the inclined surface of the pad complementary film may be connected to an inclined surface of the anti-reflective layer.

In some embodiments, an oblique neutral plane may be formed in the first section of the flexible display device when the flexible substrate undergoes bending or sliding.

According to another exemplary embodiment of the inventive concept, a flexible display device is provided. The flexible display device includes a flexible substrate including a display area and a non-display area, a display device layer positioned on the display area, an anti-reflective layer positioned on the display device layer, and a pad portion positioned in the non-display area. The anti-reflective layer includes an inclined surface, and the anti-reflective layer is connected to the pad portion at the inclined surface.

In some embodiments, the pad portion may include a pad complementary film having an inclined surface, and the inclined surface of the pad complementary film may be connected to the inclined surface of the anti-reflective layer.

In some embodiments, the anti-reflective layer may be positioned in a portion of the non-display area, and connected to a pad complementary film.

In some embodiments, the anti-reflective layer may include at least one surface formed with the inclined surface, and the anti-reflective layer may be connected to the pad complementary film through the at least one surface formed with the inclined surface.

In some embodiments, the anti-reflective layer may include three surfaces formed with inclined surfaces, and the inclined surfaces of the three surfaces of the anti-reflective layer may be connected to the pad complementary film.

In some embodiments, a pad complementary film may be connected to the anti-reflective layer in a first section of the flexible display device, and an inclined surface of the pad complementary film may be connected to the inclined surface of the anti-reflective layer.

In some embodiments, an oblique neutral plane may be formed in the first section of the flexible display device when the flexible substrate undergoes bending or sliding.

### BRIEF DESCRIPTION OF THE DRAWINGS

FIG. 1 is a plan view illustrating a flexible display device according to a first exemplary embodiment.

FIG. 2 is a cross-sectional view of the flexible display device of FIG. 1 taken along line V-V′.

FIG. 3 is a cross-sectional view illustrating a neutral plane in a change section in the flexible display device of FIG. 2.

FIG. 4 is a cross-sectional view illustrating a neutral plane in a flexible display device according to a Comparative Example.

FIG. 5 is a plan view illustrating a flexible display device according to a second exemplary embodiment.

FIG. 6 is a cross-sectional view of the flexible display device of FIG. 5 taken along line W-W′.

### DETAILED DESCRIPTION

In the following description, certain exemplary embodiments of the inventive concept have been shown and described by way of illustration. As those skilled in the art would realize, the described embodiments may be modified in various ways without departing from the spirit or scope of the present disclosure. Accordingly, the drawings and description are to be regarded as illustrative in nature and should not be construed in a restrictive manner. Like reference numerals designate like elements throughout the specification.

Throughout this specification and the claims that follow, when an element is described as being “coupled” to another element, the element may be “directly coupled” to the other element or “electrically coupled” to the other element through a third element. In addition, unless expressed otherwise, the word “comprise” and variations such as “comprises” or “comprising” will be understood to imply the inclusion of stated elements but not the exclusion of any other elements.

A flexible display device according to exemplary embodiments of the inventive concept will be described with reference to the accompanying drawings.

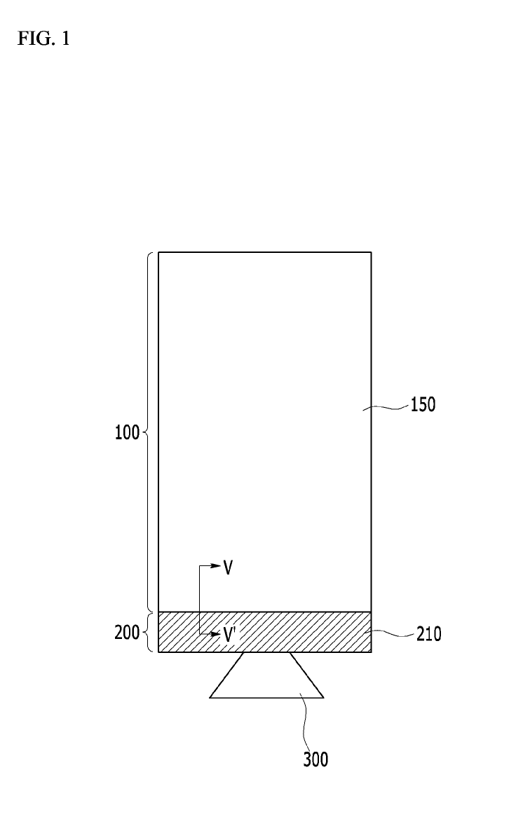

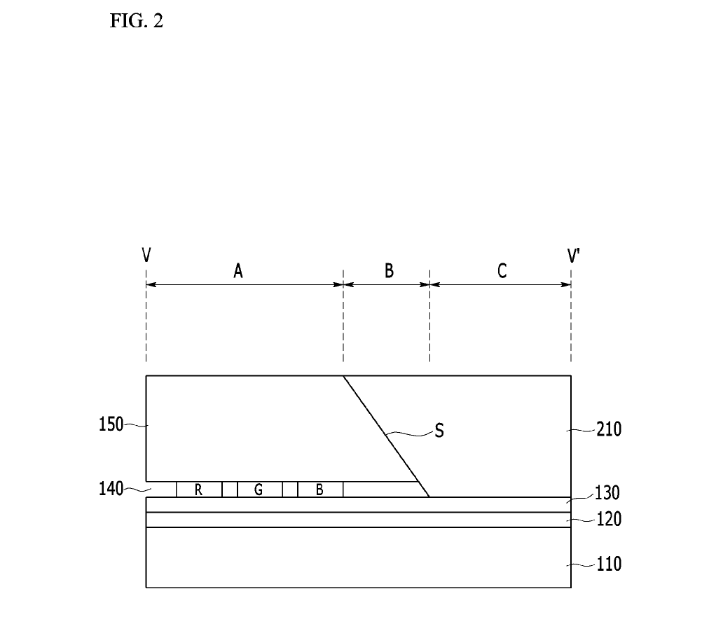

FIG. 1 is a plan view illustrating a flexible display device according to a first exemplary embodiment, and FIG. 2 is a cross-sectional view of the flexible display device of FIG. 1 taken along line V-V′.

Referring to FIGS. 1 and 2, the flexible display device according to the first exemplary embodiment includes a display area 100 and a non-display area 200. The display area 100 is an active region A for displaying an image. A pad part PAD is positioned in the non-display area 200 and connected to a chip on film (COF) 300.

The flexible display device further includes a lower protective film 110, an adhesive layer 120, a flexible substrate 130, a display device layer 140, an anti-reflective layer 150, and a pad complementary film 210.

An upper portion of the lower protective film 110 is applied with the adhesive layer 120, and the flexible substrate 130 is disposed thereon.

The lower protective film 110 may include any one of the following materials: polyethylene terephthalate (PET), polyethylene naphthalate (PEN), polyethylene sulfide (PES), or polyethylene (PE). Generally, the lower film may be made of a polymer material having good elasticity.

A thickness of the lower protective film 110 may range from about 25 μm to about 100 μm. When the thickness of the lower protective film 110 is less than about 25 μm, the lower protective film 110 will be too thin and may be unable to effectively protect a lower portion of the organic light emitting diode. On the contrary, when the thickness of the lower protective film 110 is greater than about 100 μm, the flexible display device loses its flexibility if the lower protective film is attached onto the organic light emitting diode.

The flexible substrate 130 may include flexible plastic and the like. For example, the flexible substrate 130 may include polyethylene terephthalate (PET), polyethylene naphthalate, polycarbonate, polyacrylate, polyetherimide, polyethersulfone, polyimide, or the like. The above materials impart flexibility to the flexible substrate 130 allowing it to bend easily.

An active region A of the display area on the flexible substrate 130 includes the display device layer 140 including a plurality of thin films.

The display device layer 140 includes a plurality of pixels (R, G, and B) connected to a plurality of signal lines. The pixels are positioned in the display area and arranged approximately in a matrix form. The signal lines may include a plurality of scanning signal lines for transferring scanning signals and a plurality of data lines for transferring data signals.

The anti-reflective layer 150 is disposed on the display device layer 140. The anti-reflective layer 150 may reduce external light reflection on the display device layer 140 of the display area 100, so as to improve visibility.

The anti-reflective layer 150 may include a polarizer (or polarization film) or a plurality of thin film layers. When the anti-reflective layer 150 includes a plurality of thin film layers, the plurality of thin film layers may include at least one metal thin film layer and at least one dielectric layer which are alternately stacked.

According to the exemplary embodiment of FIG. 2, the anti-reflective layer 150 has an inclined surface and may be connected to the pad complementary film 210.

A pad part C of the non-display area 200 is provided with the pad complementary film 210. According to the exemplary embodiment of the present invention, the pad complementary film 210 has the inclined surface S and may be connected to the anti-reflective layer 150.

Referring to FIG. 2, the flexible display device includes the active region A, a change section B, and a pad portion C. The active region A may be disposed in the display area 100, and the change section B and the pad part C may be disposed in the non-display area 200.

Further, the change section B is a portion where the pad complementary film 210 having the inclined surface S is connected to the anti-reflective layer 150 sharing the inclined surface S. The inclined surface S of the pad complementary film 210 may be disposed on the inclined surface of the anti-reflective layer 150.

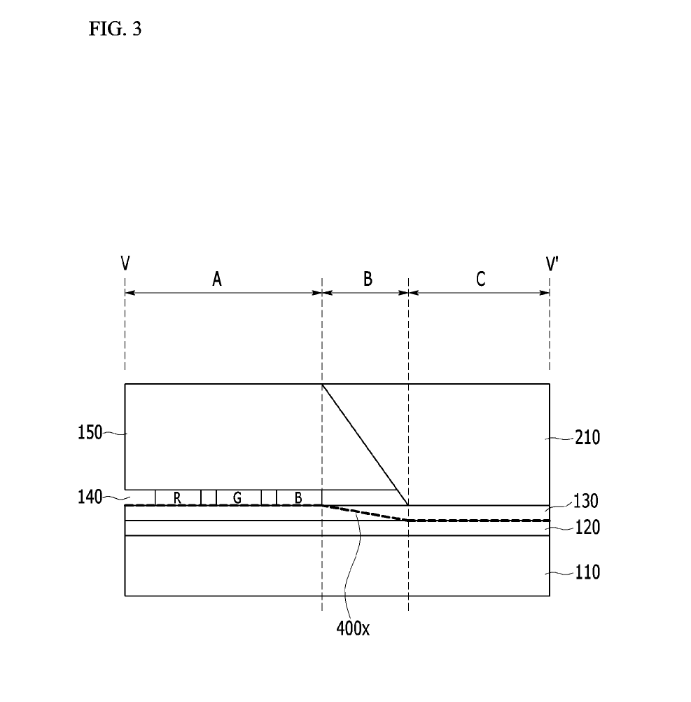

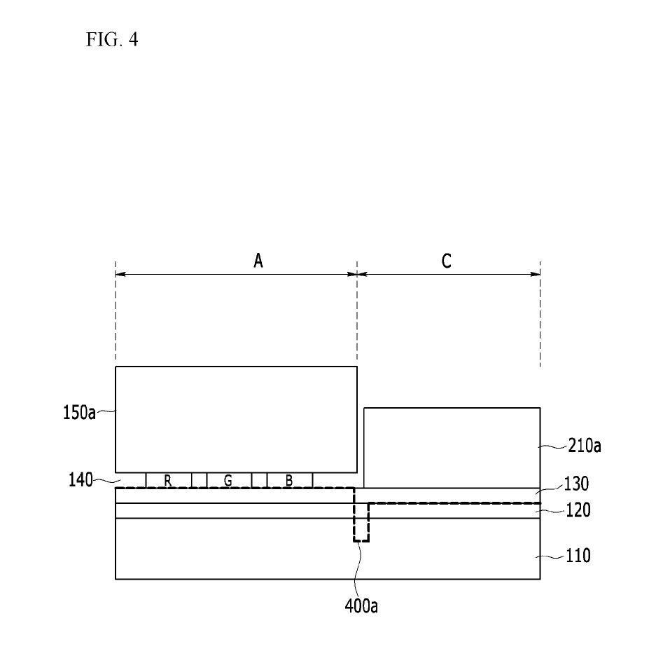

FIG. 3 is a cross-sectional view illustrating a neutral plane 400x in the change section B in the flexible display device of FIG. 2. FIG. 4 is a cross-sectional view illustrating a neutral plane 400a in a flexible display device according to a Comparative Example.

Referring to FIG. 4, in the flexible display device according to the Comparative Example, a neutral plane (NP) distortion 400a is generated due to mechanical bending or folding stress.

In the flexible display device according to the Comparative Example, during bonding of the pad complementary film 210a and the anti-reflective layer 150b, the neutral plane of the flexible display device is suddenly changed by the generation of the neutral plane distortion 400a. In particular, the region of the neutral plane distortion 400a is vulnerable to cracks.

However, in the flexible display device according to the first exemplary embodiment illustrated in FIG. 3, when the flexible substrate 130 is bent or slides, an oblique neutral plane 400x is formed in the change section B where the pad complementary film 210 is connected to the anti-reflective layer 150.

Therefore, in the flexible display device according to the first exemplary embodiment, no sudden change is generated in a curved line of the neutral plane even during sliding or bending. In some instances, the sliding or bending may even facilitate bonding tolerance since the pad complementary film 210 and the anti-reflective layer 150 are connected by the inclined surface S. As a result, inorganic layers having brittle characteristics that may be present in a back plane region in the flexible display device according to the first exemplary embodiment may be bent or folded without cracks.

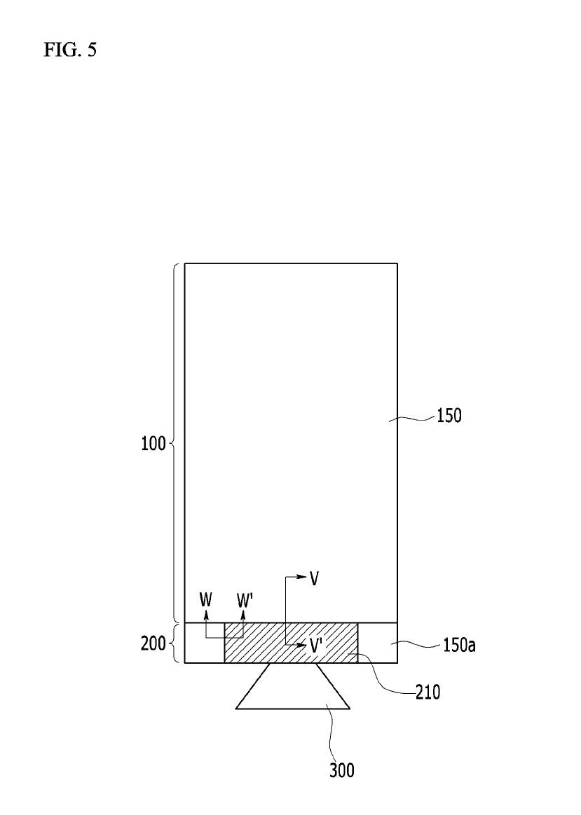

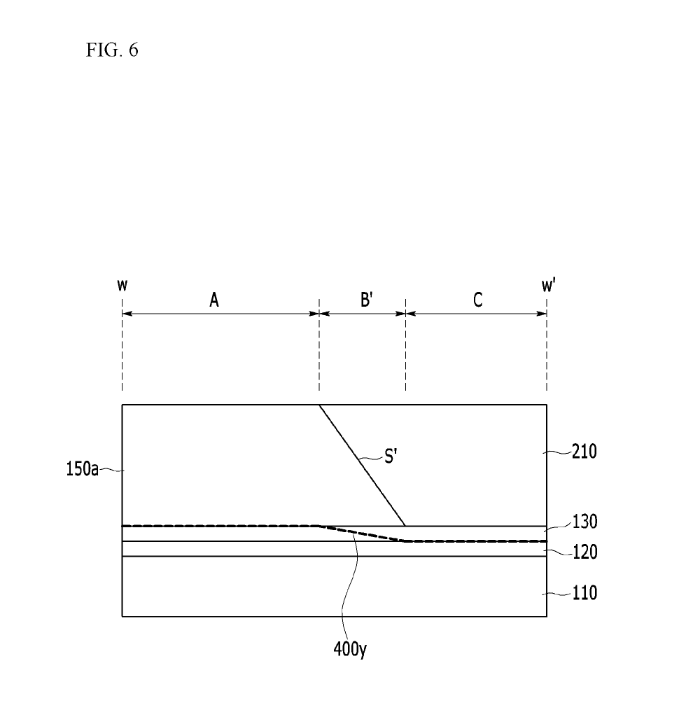

FIG. 5 is a plan view illustrating a flexible display device according to a second exemplary embodiment, and FIG. 6 is a cross-sectional view illustrating the flexible display device of FIG. 5 taken along line W-W′.

Referring to FIG. 5, in the flexible display device according to the second exemplary embodiment, the anti-reflective layer 150 may be positioned in the display area 100 and may extend up to the non-display area 200.

As previously described, in the flexible display device according to the first exemplary embodiment, the inclined surface may be formed at a portion where the pad complementary film 210 meets the anti-reflective layer 150 to connect between the pad complementary film 210 and the anti-reflective layer 150, as illustrated by the cross-sectional view V-V′ of FIG. 2. In the flexible display device according to the second exemplary embodiment, the inclined surface may be formed at a portion where the extending anti-reflective layer 150a meets the pad complementary film 210 to connect between the extending anti-reflective layer 150a and the pad complementary film 210, as illustrated by the cross-sectional view W-W′ of FIG. 6.

Referring to FIG. 6, in the flexible display device according to the second exemplary embodiment, the anti-reflective layer 150a is connected to the pad complementary film 210 having an inclined surface S′ in a change section B′. Furthermore, in the flexible display device according to the second exemplary embodiment, when the flexible substrate 130 is bent or slides in the change section B′, an oblique neutral plane 400y is formed.

Therefore, in the flexible display device according to the second exemplary embodiment, no sudden change is generated in a curved line of the neutral plane even during sliding or bending. In some instances, the sliding or bending may even facilitate bonding tolerance since the anti-reflective layer 150a is connected to the pad complementary film 210 having the inclined surface S′ in the change section B′. As a result, inorganic layers having brittle characteristics that may be present in a back plane region in the flexible display device according to the second exemplary embodiment may be bent or folded without cracks.

According to one or more of the above-described embodiments, a flexible display device includes inclined surfaces formed at an interface between a polarization film and a pad complementary film and connecting the polarization film and the pad complementary film. The inclined surfaces can minimize a sudden change in the neutral plane of the flexible display device during bonding of the polarization film and the pad complementary film.

While the inventive concept has been described in connection with what is presently considered to be exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A flexible display device comprising:
a flexible substrate including a display area and a non-display area;
an anti-reflective layer positioned in the display area; and
a pad portion positioned in the non-display area,
wherein the pad portion includes a pad complementary film having an inclined surface.

2. The flexible display device of claim 1, wherein the pad complementary film is connected to the anti-reflective layer, and the inclined surface of the pad complementary film is connected to an inclined surface of the anti-reflective layer.

3. The flexible display device of claim 1, wherein the pad complementary film includes at least one surface formed with the inclined surface.

4. The flexible display panel of claim 3, wherein the anti-reflective layer is positioned in a portion of the non-display area, and connected to the pad complementary film through the at least one surface formed with the inclined surface.

5. The flexible display device of claim 3, wherein the pad complementary film includes three surfaces formed with inclined surfaces, and the inclined surfaces of the three surfaces of the pad complementary film are connected to the anti-reflective layer.

6. The flexible display device of claim 1, wherein the pad complementary film is connected to the anti-reflective layer in a first section of the flexible display device, and the inclined surface of the pad complementary film is connected to an inclined surface of the anti-reflective layer.

7. The flexible display device of claim 6, wherein an oblique neutral plane is formed in the first section of the flexible display device when the flexible substrate undergoes bending or sliding.

8. A flexible display device comprising:
a flexible substrate including a display area and a non-display area;
a display device layer positioned on the display area;
an anti-reflective layer positioned on the display device layer; and
a pad portion positioned in the non-display area,
wherein the anti-reflective layer includes an inclined surface, and the anti-reflective layer is connected to the pad portion at the inclined surface.

9. The flexible display device of claim 8, wherein the pad portion includes a pad complementary film having an inclined surface, and the inclined surface of the pad complementary film is connected to the inclined surface of the anti-reflective layer.

10. The flexible display device of claim 8, wherein the anti-reflective layer is positioned in a portion of the non-display area, and connected to a pad complementary film.

11. The flexible display device of claim 10, wherein the anti-reflective layer includes at least one surface formed with the inclined surface, and the anti-reflective layer is connected to the pad complementary film through the at least one surface formed with the inclined surface.

12. The flexible display device of claim 10, wherein the anti-reflective layer includes three surfaces formed with inclined surfaces, and the inclined surfaces of the three surfaces of the anti-reflective layer are connected to the pad complementary film.

13. The flexible display device of claim 8, wherein a pad complementary film is connected to the anti-reflective layer in a first section of the flexible display device, and an inclined surface of the pad complementary film is connected to the inclined surface of the anti-reflective layer.

14. The flexible display device of claim 13, wherein an oblique neutral plane is formed in the first section of the flexible display device when the flexible substrate undergoes bending or sliding.
